(19) United States
(12) Patent Application Publication
(10) Pub. No.: US 2025/0300061 A1
(43) Pub. Date: Sep. 25, 2025

(54) FLEXIBLE PRINTED CIRCUIT BOARD BONDING POWER MODULE

(71) Applicant: University of Tennessee Research Foundation, Knoxville, TN (US)

(72) Inventors: Hua Bai, Knoxville, TN (US); Fei Wang, Knoxville, TN (US); Shimul Kumar Dam, Kharagpur (IN); Ching-Hsiang Yang, Knoxville, TN (US); Zhou Dong, Cary, NC (US)

(73) Assignee: University of Tennessee Research Foundation, Knoxville, TN (US)

(21) Appl. No.: 19/088,572

(22) Filed: Mar. 24, 2025

Related U.S. Application Data
(60) Provisional application No. 63/568,898, filed on Mar. 22, 2024.

(51) Int. Cl. H01L 23/498; H01L 23/00; H01L 23/31

(52) U.S. Cl. CPC H01L 23/4985; H01L 23/49833; H01L 24/32; H01L 24/83; H01L 23/3107; H01L 2224/32227; H01L 2224/83801

(57) ABSTRACT

A power electronics module and a method of making the same are disclosed. The power electronics module comprises a rigid printed circuit board (PCB); a semiconductor die; and a flexible connection coupling the rigid PCB to the semiconductor die, wherein the flexible connection remains flexible at cryogenic temperatures.

### CROSS-REFERENCE TO RELATED APPLICATIONS

This application claims benefit of and priority to U.S. Provisional Application Ser. No. 63/568,898, filed on Mar. 22, 2024, the disclosure of which is incorporated herein by reference in its entirety.

### GRANT STATEMENT

This invention was made with government support under Award Number-DE-AR0001467 awarded by the Advanced Research Projects Agency-Energy (ARPA-E), U.S. Department of Energy. The government has certain rights in the invention.

### BACKGROUND

Power modules typically use direct bonded copper (DBC) to mount power semiconductor dies, as it offers excellent electrical isolation and low thermal resistance for heat dissipation. However, due to differences in the coefficients of thermal expansion (CTE) between the die, DBC, encapsulation material, and printed circuit board (PCB) material, soldering the dies directly to a rigid PCB is not feasible. To address this, the die pads are connected to the power module terminals primarily through thin wire bonding. Unfortunately, this method results in high inductance and reduced reliability.

### SUMMARY

A power electronics module and a method of making the same are disclosed. In some embodiments, the power electronics module comprises a rigid printed circuit board (PCB); a semiconductor die; and a flexible connection coupling the rigid PCB to the semiconductor die, wherein the flexible connection remains flexible at cryogenic temperatures.

In some embodiments, a power electronics module is disclosed. In some embodiments, the power electronics module comprises: a rigid printed circuit board (PCB) having a slot cut-out; a semiconductor die within the slot cut-out of the rigid PCB, wherein a top surface of the semiconductor die is lower than a top surface of the rigid PCB; and at least one flexible PCB coupled to the semiconductor die and the rigid PCB, wherein the flexible PCB rises from the semiconductor die to a point higher than the top surface of the rigid PCB.

In some embodiments, the semiconductor die and the rigid PCB are mounted on a direct bonded copper (DBC) structure. In some embodiments, the rigid PCB is bonded to the DBC structure using an insulation coating. In some embodiments, the semiconductor die is soldered to the DBC structure, and wherein the flexible PCB is soldered to one or more first die pads on the semiconductor die and one or more connection points on the rigid PCB.

In some embodiments, an encapsulation material encasing the semiconductor die.

In some embodiments, the flexible PCB comprises two copper layers configured for power and signal connection to the semiconductor die or wherein power and signal connection is paralleled in a same layer. In some embodiments, the flexible PCB comprises a flexible core layer between the two copper layers or wherein the flexible PCB comprises multiple copper layers with a flexible inner layer. In some embodiments, a ratio between a thickness of the flexible core and a thickness of the copper layers is about 1:3.

In some embodiments, the flexible PCB comprises a bent shape that curves from the semiconductor die to the point higher than the top surface of the rigid PCB and then curves back down to the rigid PCB.

In some embodiments, the semiconductor die comprises a GaN high electron mobility transistor (HEMT), SiC, Si MOSFET, an IGBT, or any combination thereof, optionally wherein a surface area of the flexible PCB is less than a surface area of the rigid PCB.

In some embodiments, a power electronics module is disclosed. In some embodiments, the power electronics module comprises: a main rigid PCB and a support rigid PCB having a cut-out and attached to the main rigid PCB on first side of the support rigid PCB; one or more semiconductor dies sealed within the cut-out of the support rigid PCB and coupled to the main rigid PCB via one or more PCB pads per one or more semiconductor dies on a first side of the one or more semiconductor dies; and a metal layer comprising a metal that remains soft down to cryogenic temperature, the metal layer coupled to the one or more semiconductor dies on a second side of the one or semiconductor dies opposite the first side of the one or more semiconductor dies. In some embodiments, the metal layer comprises a metal that remains soft in a temperature range from maximum die temperature down to cryogenic temperature and/or from a melting temperature for the metal down to cryogenic temperature.

In some embodiments, the metal layer and the support rigid PCB are disposed on a direct bonded copper (DBC) structure. In some embodiments, the support rigid PCB and the metal layer are soldered to the DBC structure and a height of the support rigid PCB is slightly lower that a height of a total thickness of the metal layer and the one or more semiconductor dies.

In some embodiments, the metal layer comprises indium or tin.

In some embodiments, the power electronics module comprises an encapsulation material encasing one or more semiconductor dies.

In some embodiments, the one or more semiconductor dies comprises two or more semiconductor dies.

In some embodiments, the power electronics module further comprises a plate or wire attached at one end to a drain pad of the main PCB and at its opposite end between the one or more vertical semiconductor dies and the metal layer.

In some embodiments, a method for manufacturing a power electronics module is provided. In some embodiments, the method comprises: connecting a semiconductor die to a direct bonded copper (DBC) structure; connecting a rigid printed circuit board (PCB) to the DBC structure; and coupling the semiconductor die and the rigid PBC with a flexible connection, wherein the flexible connection remains flexible at cryogenic temperatures.

In some embodiments, a method for manufacturing a power electronics module is provided. In some embodiments, the method comprises: bonding a semiconductor die to a direct bonded copper (DBC) structure; bonding a rigid printed circuit board (PCB) to the DBC structure so that the semiconductor die is within a slot cut-out of the rigid PCB; and coupling at least one flexible PCB to the semiconductor die and the rigid PBC, wherein the flexible PCB rises from the semiconductor die to a point higher than the top surface of the rigid PCB.

In some embodiments, the method comprises pouring encapsulation material through the slot cut-out of the rigid PCB over the semiconductor die.

In some embodiments, bonding the semiconductor die to the DBC structure comprises soldering the semiconductor die to the DBC structure.

In some embodiments, bonding the rigid PCB to the DBC structure comprises bonding the rigid PCB with an insulation coating.

In some embodiments, coupling the flexible PCB to the semiconductor die and the rigid PCB comprises soldering the flexible PCB to the semiconductor die and the rigid PCB.

In some embodiments, the flexible PCB comprises two copper layers configured for power and signal connection to the semiconductor die or wherein power and signal connection is paralleled in a same layer. In some embodiments, the flexible PCB comprises a flexible core layer between the two copper layers or wherein the flexible PCB comprises multiple copper layers with a flexible inner layer. In some embodiments, a ratio between a thickness of the flexible core and a thickness of the copper layers is about 1:3.

In some embodiments, the flexible PCB comprises a bent shape that curves from the semiconductor die to the point higher than the top surface of the rigid PCB and then curves back down to the rigid PCB.

In some embodiments, a method for manufacturing a power electronics module is provided. In some embodiments, the method comprises: disposing a metal layer and a support rigid PCB having a cut-out on a direct bonded copper (DBC) structure, the metal layer comprising a metal that remains soft down to cryogenic temperature; attaching a main rigid PCB on first side of the support rigid PCB; coupling one or more semiconductor dies to the main rigid PCB via one or more PCB pads per one or more semiconductor dies on a first side of the one or more semiconductor dies, such that the one or more semiconductor dies are sealed within the cut-out of the support rigid PCB; and coupling the one or more semiconductor dies to the metal layer on a second side of the one or semiconductor dies opposite the first side of the one or more semiconductor dies. In some embodiments, the metal layer comprises a metal that remains soft in a temperature range from maximum die temperature down to cryogenic temperature and/or from a melting temperature for the metal down to cryogenic temperature.

In some embodiments, the metal layer and the support rigid PCB are disposed on a direct bonded copper (DBC) structure. In some embodiments, the support rigid PCB and the metal layer are soldered to the DBC structure and a height of the support rigid PCB is slightly lower that a height of a total thickness of the metal layer and the one or more semiconductor dies.

In some embodiments, the metal layer comprises indium or tin.

In some embodiments, the power electronics module comprises an encapsulation material encasing one or more semiconductor dies.

In some embodiments, the one or more semiconductor dies comprises two or more semiconductor dies.

In some embodiments, the power electronics module further comprises a plate or wire attached at one end to a drain pad of the main PCB and at its opposite end between the one or more vertical semiconductor dies and the metal layer.

Accordingly, it is an object of the presently disclosed subject matter to provide power electronics modules; and methods of preparing power electronics modules.

An object of the presently disclosed subject matter having been stated hereinabove, and which is achieved in whole or in part by the presently disclosed subject matter, other objects will become evident as the description proceeds hereinbelow.

### BRIEF DESCRIPTION OF DRAWINGS

FIG. 1 shows an example power electronics module.

FIG. 2 is a perspective view of the example power electronics module showing some other example components on the rigid PCB.

FIGS. 3A-3D illustrate an example manufacturing method for power electronics packaging by showing top views of the power electronics module.

FIG. 4 is a front view of an example packaging for single die.

FIG. 5 is a bottom view of an example packaging for single die before soldering DBC.

FIG. 6 is a front view of an example packaging for multiple die.

FIG. 7 is a bottom view of an example packaging for multiple die before soldering DBC.

FIG. 8 illustrates an example packaging for multiple dies for vertical devices.

### DETAILED DESCRIPTION

This document describes electronics packages and packaging methods that can be used to reduce inductance, among other advantages. A flexible PCB is directly soldered or sintered on the die pads. This approach reduces the inductance of the power loop and improves switching performance of the dies significantly.

In some conventional flex PCB-based approaches, packaging methods rely on the flexibility of the flex PCB materials to reduce the mechanical stress on dies due to CTE mismatch among different components of the power module. However, the capability of mechanical stress reduction during thermal cycling is limited by the flexibility of the flex PCB material. Thus, in certain applications such as cryogenic applications, where the power module is subjected to thermal cycling over a very wide range, the flexibility of flex PCB alone may not be sufficient.

Another potential drawback of the flex PCB approach is its high cost due to the use of high-performance flexible material instead of standard material such as FR4 for PCB construction. The dies are sandwiched between the flex PCB layer and the DBC, making it difficult to fill all the voids around the dies with encapsulation material, leading to reliability concerns, especially for high voltage applications, and the need for a more precise and costlier manufacturing process.

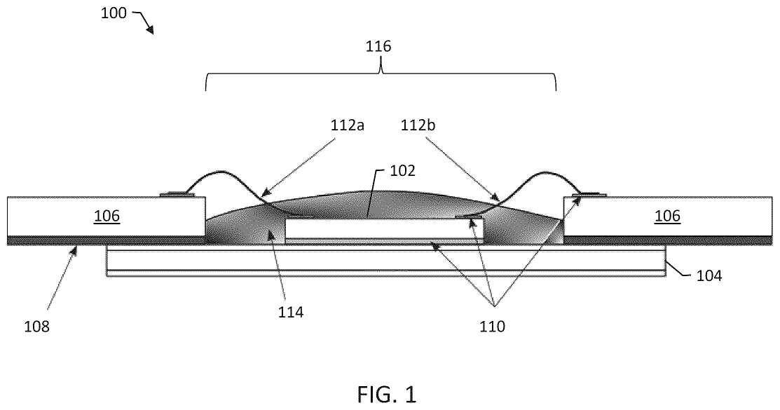

This document describes examples of power module packaging methods to achieve wider thermal cycling capability and to simplify the process and reduce the cost of manufacturing. FIG. 1 shows an example power electronics module 100. Power electronics modules are electronic components that convert and control electrical power. They are used in a wide range of applications, including motor drives, power supplies, and renewable energy systems. In aircraft, power electronics modules are often used to convert AC power at certain voltages and frequencies from the airplane's engines or generators into DC power or AC power at different voltages and frequencies that can be used by the electronic systems onboard.

As shown in FIG. 1, a semiconductor die 102 is soldered to a DBC structure 104 using solder paste 110. A rigid PCB 106 surrounds or partially surrounds the die 102, e.g., within a slot cut-out 116 from the rigid PCB 106. In general, the rigid PCB 106 surrounds the die 102 on all sides to enable encapsulation. Encapsulation material 114 encases the die 102. The die 102 can be, for example, a gallium nitride (GaN) high electron mobility transistor (HEMT). However, any suitable transistor or other suitable material as would be apparent to one of ordinary skill in the art upon a review of the instant disclosure can be implemented as die 102.

A GaN HEMT is a type of transistor that is used in high-frequency, high-power electronic applications. It is a variant of the Silicon Metal Oxide Semiconductor Field-Effect Transistor (MOSFET), which is a common type of transistor used in power electronics circuits. In some examples of a conventional structure of a GaN HEMT GaN semiconductor material is grown on a silicon (Si) substrate, after which an Aluminum Gallium Nitride (AlGaN) layer is formed. The large difference in thermal expansion coefficients between GaN and Si can cause substantial stress during cooling after crystal growth, potentially leading to cracks in the substrate. A buffer layer is provided to relieve this stress. See https://www.rohm.com/electronics-basics/gan/gan-hemt.

In some embodiments, the die 102 can comprise, for example, a GaN HEMT, silicon carbide (SiC), Si MOSFET, an Insulated-Gate Bipolar Transistor (IGBT), or any combination thereof. In some embodiments, a surface area of the flexible PCB is less than a surface area of the rigid PCB.

The high-frequency operation of GaN HEMTs makes them useful in a variety of applications, including power amplifiers for wireless communications, radar systems, and power converters for renewable energy systems. They offer several advantages over other high-frequency transistors, including higher efficiency, smaller size, and better reliability.

Direct Bonded Copper (DBC) is a technology used in power electronics modules to improve heat dissipation and electrical performance. In the DBC structure 104, two layers of copper are directly bonded to a ceramic substrate layer, typically made of aluminum oxide (Al₂O₃) or aluminum nitride (AlN).

The DBC process can include cleaning and polishing both the copper and ceramic surfaces to remove any impurities or surface irregularities. The cleaned surfaces are then pressed together under high pressure and high temperature to create a strong, permanent bond between the copper and ceramic layers. The resulting DBC structure 104 provides several advantages for power electronics applications. Both the copper and the ceramic layers provide excellent thermal conductivity, which helps dissipate heat generated by the electronic components. The ceramic substrate provides excellent electrical insulation, which helps prevent short circuits and electrical breakdowns.

The rigid PCB 106 is typically a board made of insulating material that is used to connect and support electronic components. One of the most used materials for PCBs is FR4, which is a type of fiberglass-reinforced epoxy laminate. FR4 PCBs can have multiple layers of fiberglass cloth that are impregnated with epoxy resin and then cured under heat and pressure. The cured fiberglass layers are then stacked and bonded together with layers of copper foil, which are etched to create the electrical pathways between the components.

The rigid PCB 106 can be manufactured, e.g., using standard FR4 material and standard manufacturing process. FR4 PCBs can be manufactured using a variety of techniques, including photolithography and drilling. In photolithography, a pattern is etched onto a layer of photosensitive material that is then used to transfer the pattern onto the copper foil layer. In drilling, holes are drilled through the PCB to create vias that connect the layers of copper foil.

In some embodiments, the slot cut-out 116 area is larger than the die 102 area. The rigid PCB 106 can be coated with electrically insulating coating 108 on the bottom side while one or more other electrical components of the power modules such as integrated circuits (ICs), passive devices, and the like can be soldered on the top side of the rigid PCB 106. The die 102 is placed inside the slot 116 of the rigid PCB 106 and die pads are connected to the rigid PCB 106 using flex PCB 112a-b. The flex PCB 112a-b, in some examples, is as wide as the length of the die 102 (or substantially the same length as the die 102) to provide low inductance and low resistance connection to the dies.

The flexible PCB 112a-b as shown in this example has a length longer than the distance between the rigid PCB 106 and die pads. The additional length of the flex PCB 112a-b is used to bend the flex PCB 112a-b as shown in FIG. 1. The flex PCB 112a-b starts from a low point at the die pads on the die 102, rises to a high point above the corresponding pads or connection points on the rigid PCB 106, and then curves down to those pads or connection points on the rigid PCB 106. This bend in the flex PCB 112a-b allows higher mismatch of thermal expansion between the rigid PCB 106 and the die 102 compared to some conventional flex PCB-based packaging, where a straight flex PCB is used.

A flex PCB is a type of printed circuit board that is made from flexible materials such as polyimide, polyester, or PEEK. Flex PCBs are designed to bend, twist, and conform to the shape of the device or product they are used in, allowing for greater design flexibility and space savings. The construction of a flex PCB is similar to that of a rigid PCB, but instead of using a rigid substrate material, a thin layer of flexible material is used. This flexible layer is typically a polymer film that is coated with a thin layer of conductive material such as copper. The conductive traces on the flexible layer can be created using photolithography, just like rigid PCBs. Flex PCBs can be designed with single or multiple layers of flexible material, depending on the complexity of the circuit design.

The flex PCB 112a-b shown in FIG. 1, in some examples, has two copper layers that are utilized for both power and signal connection to the die 102. In some embodiments, the power and signal connection is paralleled in the same layer. The flex PCB 112a-b can also have a flexible core layer between two copper layers to provide flexibility. In some embodiments, the flexible PCB comprises multiple copper layers with a flexible inner layer. However, if the flexible core thickness is much higher than the copper layer thickness, the flex connection will be highly flexible and elastic, and it will not be able to retain its bent shape as shown in FIG. 1. The ratio of core to copper layer can be selected to achieve sufficient stiffness to retain the bent shape while also having sufficient flexibility to allow for thermal expansion and contraction. In some examples, a 1:3 ratio of core to copper layer (or a ratio of about to 1:3) provides enough flexibility while retaining the special shape of the flex PCB.

In some cases, the flex PCB 112a-b covers a small area of the power module 100 while the rigid PCB 106 contains other components and facilitates connections to the external terminals of the module 100, the additional cost of using flex PCB is much smaller than some types of conventional flex PCB based packaging.

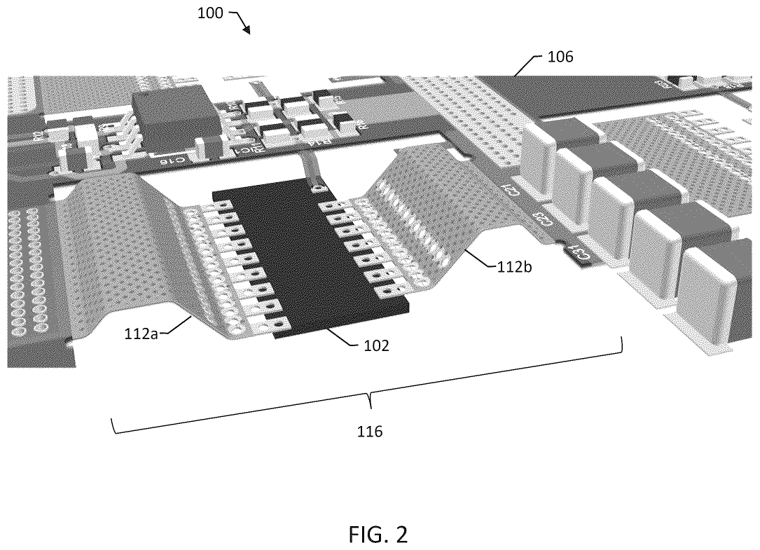

FIG. 2 is a perspective view of the example power electronics module 100 showing some other example components on the rigid PCB 106. As can be seen in FIG. 2, the die 102 sits within the slot 116 of the rigid PCB 106 at a lower height than the rigid PCB 106. Flex PCB 112a on the left and flex PCB 112b on the right couples the die 102 to the rigid PCB 106.

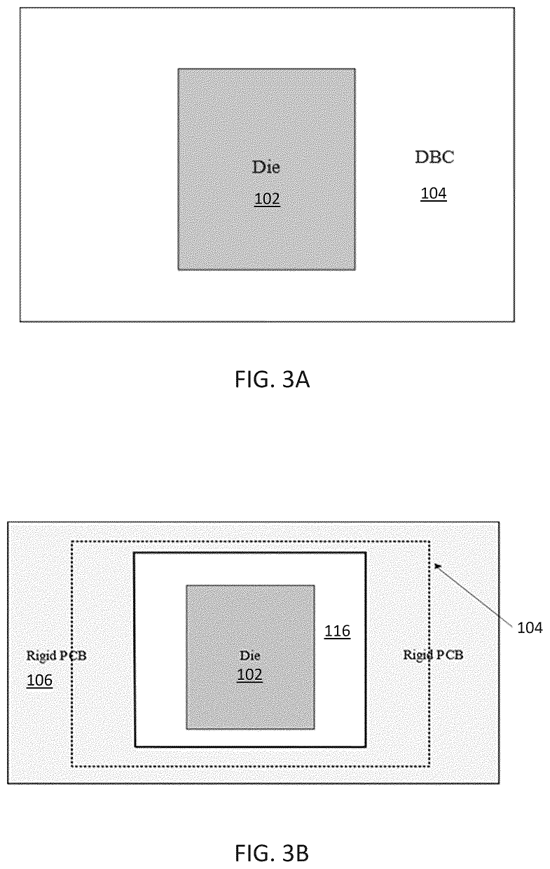

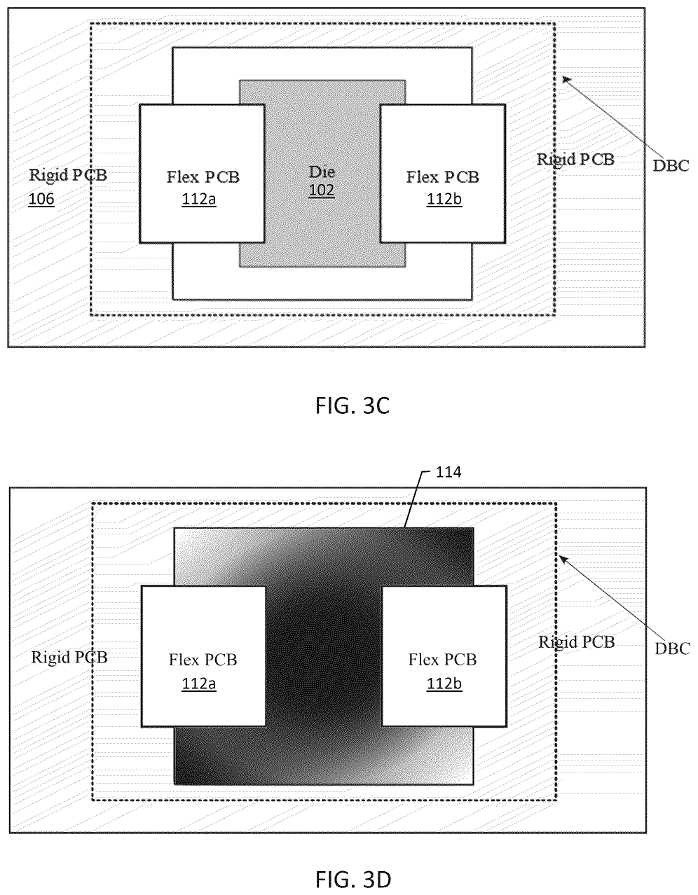

FIGS. 3A-3D illustrate an example manufacturing method for power electronics packaging by showing top views of the power electronics module 100. The method can be simpler and more cost-effective than some conventional flex PCB approaches. The method can include the four steps shown in FIG. 3A-3D and, in some examples, other steps.

FIG. 3A shows a first step where the die 102 is soldered on the DBC 104 using solder paste. FIG. 3B shows a second step where the rigid PCB 106 with slot cut-out 116 and bottom side coated is placed on the DBC 104 so that the die 102 stays inside the PCB slot 116. FIG. 3C shows a third step where the properly bent flex PCBs 112a-b are placed on the die 102 and the rigid PCB 106 and soldered using solder paste. FIG. 3D shows a fourth step where the encapsulation material 114 is poured over the die 102. Since the area around the die is exposed from the top side, the encapsulation material can easily flow and encapsulate the entire die and get rid of any void around it. This method of encapsulation is simple and highly reliable and is possible due to the structure of the rigid-flex PCB connection.

The example power module 100 is capable of withstanding a wide range of temperature variation due to the bendable shape of the flex PCB connections 112a-b. However, the encapsulation material 114 should also be chosen carefully so that it does not exert high stress on the die 102 during thermal cycling. In order to ensure that, the CTE of the encapsulation material 114 can be chosen to be close to the CTE of copper. Since the top surface of the die 102 can have a metal layer with a CTE close to that of copper, the flex connections and properly selected potting material do not apply any significant additional stress on the die 102 during thermal cycling.

This packaging strategy enables the die 102 to survive much wide and fast thermal cycling. Apart from CTE matching, a potting material can be chosen with a low glass transition temperature. The commonly used silicone gel material provides good insulation for power modules working at normal temperatures (−40° C. to 175° C.). However, silicone gel cracks at cryogenic temperature (<−153° C.). In some examples, the module 100 uses epoxy based potting material which has a CTE close to that of copper and a low glass transition temperature. With this packaging, the power module 100 is capable of reliably operating from cryogenic temperatures to maximum temperature allowed by safe operation of the die.

In some examples, the power module 100 is incorporated into a cryogenic system. The cryogenic system can be used on aircraft. Cryogenic cooling is the process of cooling electronic components to extremely low temperatures, typically below −150° C. (−238° F.), to improve their performance and increase their lifespan. Cryogenic cooling is used in various electronic systems, including superconducting systems, microwave systems, and infrared sensors.

Superconducting systems, such as superconducting magnetometers used for geomagnetic research, require cryogenic cooling to maintain their superconducting properties. These systems are typically cooled using liquid helium.

Microwave systems, such as those used for radar and communication, can also benefit from cryogenic cooling. Cryogenic cooling can improve the signal-to-noise ratio of these systems, allowing for more accurate measurements and better communication. These systems are typically cooled using liquid nitrogen.

Infrared sensors used for thermal imaging and other applications also often require cryogenic cooling. Cryogenic cooling can reduce the thermal noise in the sensor, allowing for more sensitive measurements. These sensors are typically cooled using a closed-cycle cryocooler, which uses a refrigeration cycle to cool the sensor.

The power electronics module 100 can be used in any appropriate system. For example, in a superconducting system, power electronics modules could be used to control the flow of electrical power to the superconducting magnetometers. In a microwave system, power electronics modules could be used to control the power and frequency of the microwaves. In an infrared sensor, power electronics modules could be used to control the readout circuitry.

In addition to their use in power conversion and control, power electronics modules can also be used for thermal management in cryogenically cooled systems. For example, they could be used to control the temperature of the cooling fluid or to regulate the temperature of the electronic components themselves.

In some examples, a surface area of the flex PCB 112a-b is smaller than a surface area of the rigid PCB 106 or a surface area of the whole power module 100. For example, the surface area of the flex PCB 112a-b can be one tenth or smaller than the surface area of the rigid PCB 106. This reduction in surface area of the flex PCB 112a-b can reduce the cost and complexity of the power module 100.

The following section describes example packaging methods that do not use flex PCB, and this section is provided for the purpose of illustration and not limitation. In these examples, a standard rigid PCB is used and the die is soldered or sintered directly on the PCB.

The following example embodiments of a power electronics module can be used in power converters and can be used in working under a wide temperature range, including Cryogenic Temperatures in Cryogenic Applications such as Datacenters, Quantum Computing, and Space applications.

A power module can include multiple semiconductor dies to improve its current and voltage ratings. The use of bare die enables close integration of multiple dies to achieve better current and voltage sharing. Traditionally, each die is attached to a base plate or a direct bond copper (DBC) on one side and wire bonding on the other side to establish electrical connections to the die pads. The wire bonds can bend during thermal cycling which can relieve stress on die-pads from mismatch of coefficients of thermal expansion (CTE) of different materials such as DBC, PCB, and metal connectors. But, the wire bonding method further suffers from limitations such as higher inductance, lower current carrying capability, and lower reliability, mainly due to the bending during thermal cycling mentioned above.

A major cause of module failure can be attributed to wire bond failure. To solve this problem, an alternate solution, as disclosed herein above, is to replace the wire bonds with flexible PCB (flex-PCB). The flex PCB can provide reduced inductance, higher current carrying capability, and high reliability. However, due to flexible nature of the flex-PCB connection to die, it is challenging to bend it precisely during soldering, especially with automated manufacturing.

The die is desirably enclosed with insulating material to protect it from environment. This is achieved by soft silicone gel, which allows the bending of wire bonds and flex-PCB during thermal cycling. However, the silicone gel loses its elasticity at low temperatures and cracks. Thus, silicone gel cannot provide effective protection from environment. An alternate potting material that does not crack at low-temperatures is epoxy resin. Although it works effectively to provide protection, it is rigid, unlike the silicone gel, and takes away the flexibility of both wire bond and flex-PCB connections. Thus, the dies in low-temperature applications either fail from environmental exposure in long term or from mechanical stress due to rigid connections and CTE mismatch.

In accordance with some embodiments of the present subject matter, a packaging strategy is disclosed herein to provide flexible connection using soft metal such as indium, tin, or a combination thereof. Thus, the soft metal can provide for the flexible connection. The term “soft” means it can be easily deformed, worked on without breaking, and is suitable for a packaging purpose as disclosed herein. For relatively common metals, indium is softest. Tin is not as soft but can also be used. In some embodiments of the presently disclosed subject matter, the melting temperatures of a soft material can range from about 150° C. to about 250° C. for packaging and soldering, including GaN packaging and soldering. It is desirable if this material can be non-toxic, stable in air, and easy to handle. In some embodiments, a “soft” material can remain soft even at cryogenic temperatures. In some embodiments, the metal layer can comprise a metal that remains soft down to cryogenic temperature. In some embodiments, the metal layer comprises a metal that remains soft in a temperature range from maximum die temperature down to cryogenic temperature and/or from a melting temperature for the metal down to cryogenic temperature. A maximum die temperature can depend on the die that is used, or the components thereof, as would be apparent to one of ordinary skill in the art upon a review of the instant disclosure. With this packaging, the power module 400 is capable of reliably operating from cryogenic temperatures to maximum temperature allowed by safe operation of the die.

In some embodiments, the soft metal (e.g., indium), does not need to be to be soft to maximum die temperature (such as a GaN die) temperature. Rather, in some embodiments, the soft metal should not melt below 150° C. Thus, in some embodiments, the soft metal can have one or more, or all, of the following criteria.
1. Soft at room temperature and down to cryogenic temperatures;
2. Melting point>150° C. (such as for GaN packaging);
3. Melting point<maximum allowable temperature for the device while soldering (e.g., 250° C. for GaN);
4. Non-toxic; and
5. Stable in air and easy to handle.

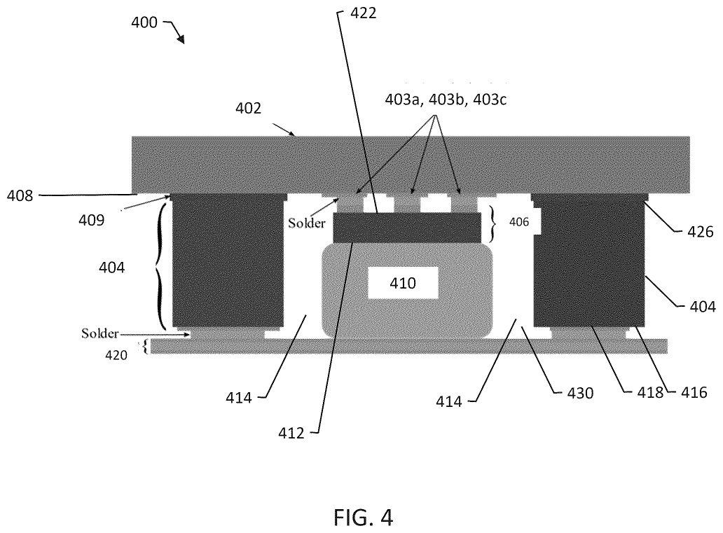

Referring now to FIGS. 4-8, in example embodiments of the presently disclosed method, two rigid PCBs are used in a power electronics module 400. One is main PCB 402 that contains all other circuitry such as gate driver and the other is a support PCB 404. The dies 406 are soldered directly on the bottom side 408 of the main PCB 402 at PCB pads 403a, 403b, and 403c for drain, source, and gate. A layer 410 of a metal, such as indium, is attached to the other side 412 of the die 406 by heating the die-indium assembly beyond the melting point of indium. The support PCB 404 is attached on the bottom side 408 of the main PCB 402, such as by soldering or by sealing with epoxy resin, referred to at 409. This support PCB 404 has cut-outs 414 such that dies 406 can stay inside them when the two PCBs 402, 404 are attached. In some embodiments, the height of the support PCB is slightly lower than the height of the total thickness of indium layer 410 and die 406. In some embodiments, the other side 416 of the support PCB 404 has a copper pad 418. A DBC 420 is then placed on the support PCB 404 with solder paste and heated up till both solder paste and indium layer 410 melt. Thus, the DBC 420 gets soldered to both support PCB 404 and indium layer 410. The two PCBs 402, 404 along with the DBC 420 create sealed space 430 around the die 406 to provide protection from environment, while the indium layer 410 provides soft, flexible thermal interface between die 406 and DBC 420.

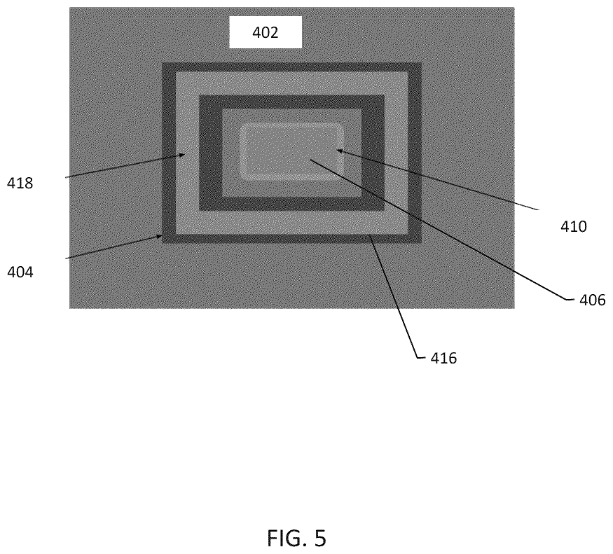

The process is explained for single die packaging first using FIGS. 4 and 5. As shown in FIG. 4, the die 406 is placed in cut-out 414 of support PCB 404. The top side 422 of the die 406 is soldered to the rigid PCB 402 and the bottom side 412 is attached to a layer 410 of indium. The support PCB 404 is designed with a cut-out 414 in the middle which is bigger than the die area and placed around the die 406, as shown in the bottom view in FIG. 5. The support PCB 404 has a continuous copper pad 418 on its bottom side 416 all around the die 406. The DBC 420 is then placed on the support PCB 404 and soldered using solder paste. The indium layer 410 also melts in the process and gets attached to the surface of the DBC 420.

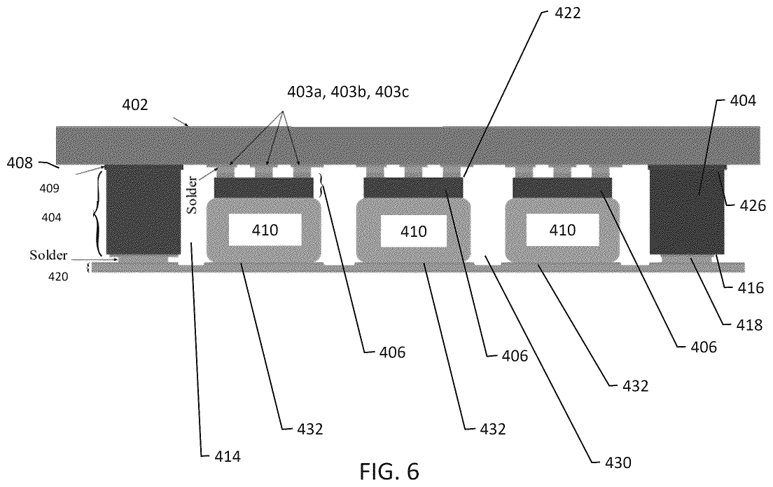

The support PCB 404 surrounds the die 406 from all directions and is attached to the main PCB 402 and DBC 420 on the top and bottom sides 426, 416, respectively, of support PCB 404 (see, for example, FIGS. 4 and 6). This structure creates a sealed area 430 as shown in FIG. 4, protecting the die 406 from environment. The indium layer 410 provides a good thermal interface between die 406 and DBC 420. The indium remains soft at cryogenic temperature and relieves mechanical stress on die from CTE mismatch among main PCB 402, support PCB 404, and DBC 420.

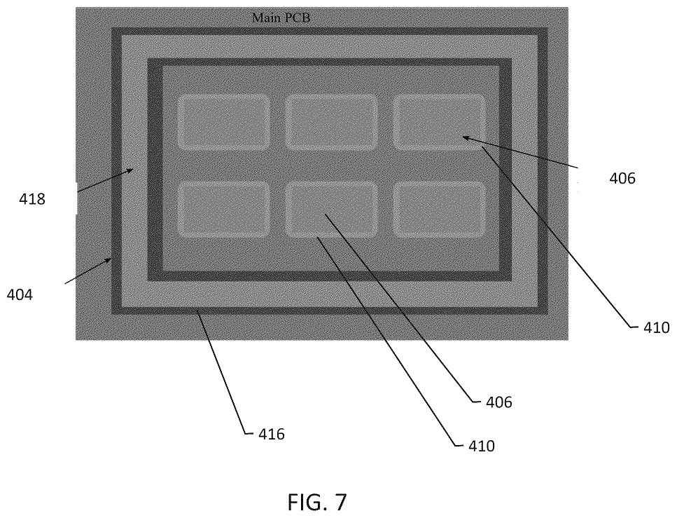

The proposed packaging can be extended to multiple die packaging, enabling its application in power module development. The multiple die package structure is similar to the single die package, as shown in FIG. 6. The cut-out 414 of the support PCB 404 is now larger to accommodate all the dies 406 as shown in FIG. 7. The DBC 420 has separate copper pad 432 for each die 406 to provide electrical insulation. The indium layers 410 too are separately applied on different dies 406. The clearance between the dies 406 is dictated only by electrical insulation requirements. Hence, the dies 406 can be closely placed for a low-inductance packaging. The dies 406 can be the same or one or more dies 406 can be different from the others.

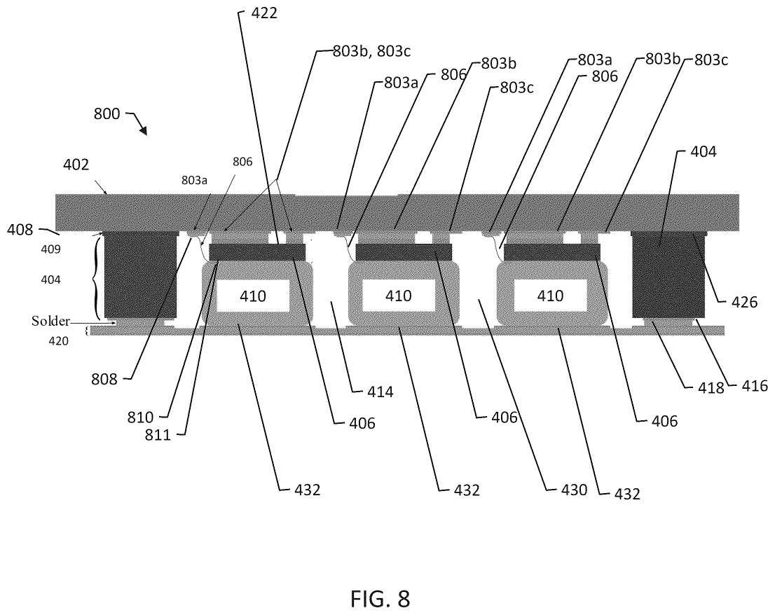

The packaging method discussed so far is for semiconductor devices with lateral structures, where the gate, drain, and source pads are on same side. Referring to FIG. 8, in the case of a vertical structure device 800, a drain pad 811 is on the other side of the die 406. In that case, all die pads cannot be directly soldered on PCB pads, 803b, 803C. A slight modification is needed in the proposed packaging in the case of vertical devices.

The module structure remains the same. The gate and source pads are directly soldered to the main PCB 402 like the lateral devices 400. The drain pad is on the bottom side of the die 406, which is soldered to indium layer 410. The modified packaging 800 is shown in FIG. 8. An additional element, a copper plate 806 is used to achieve electrical connection between drain pad 803a (the pad on the PCB for drain connection) and main PCB 402. The copper plate 806 is bent, and its one end 808 is soldered on drain pad 803a of main PCB 402. The other end 810 is placed between die 406 and indium layer 410 at a location of drain pad 811 before heating up the assembly for DBC soldering. When the assembly is heated up for DBC soldering, the Indium melts and creates a good electrical connection between the surface of die 406 and copper plate 806. The copper plate 806 can be replaced with wire bonds too, but it leads to lower reliability and less current capability.

As discussed herein above for die 102, die 406 can be, for example, a gallium nitride (GaN) high electron mobility transistor (HEMT). However, any suitable transistor or other suitable material as would be apparent to one of ordinary skill in the art upon a review of the instant disclosure can be implemented as die 102.

A GaN HEMT is a type of transistor that is used in high-frequency, high-power electronic applications. It is a variant of the Silicon Metal Oxide Semiconductor Field-Effect Transistor (MOSFET), which is a common type of transistor used in power electronics circuits. In some examples of a conventional structure of a GaN HEMT, GaN semiconductor material is grown on a silicon (Si) substrate, after which an Aluminum Gallium Nitride (AlGaN) layer is formed. The large difference in thermal expansion coefficients between GaN and Si can cause substantial stress during cooling after crystal growth, potentially leading to cracks in the substrate. A buffer layer is provided to relieve this stress. See https://www.rohm.com/electronics-basics/gan/gan-hemt.

In some embodiments, the die 406 can comprise, for example, SiC, Si MOSFET, an IGBT, or any combination thereof. In some embodiments, a surface area of the flexible PCB is less than a surface area of the rigid PCB.

The presently disclosed subject matter may provide one or more of the following advantages over some conventional systems.
Die can be sealed with PCB, DBC, and solder, whose properties do not change at cryogenic temperature. Hence, protection from environment is available at low temperatures.
The indium layer provides good thermal and electrical connections to DBC, while providing a soft interface to DBC even at cryogenic temperatures to relieve mechanical stress.
The presently disclosed packaging can survive very challenging cryogenic thermal cycling, which other power module packaging methods cannot.
Die pads are directly soldered on PCB containing gate driver, leading to very low loop inductances.
No additional space is needed around lateral dies for electrical connections. One copper plate connection is needed on the side of vertical die. Multiple dies can be more closely placed for lower parasitics and better voltage and current sharing.

Unless otherwise defined, all technical and scientific terms used herein have the same meaning as commonly understood by one of ordinary skill in the art to which the presently described subject matter belongs. All publications, patent applications, patents, and other references mentioned herein are incorporated by reference in their entirety.

Following long-standing patent law convention, the terms “a”, “an”, and “the” refer to “one or more” when used in this application, including the claims. Thus, for example, reference to “a component” includes a plurality of such components, and so forth.

Unless otherwise indicated, all numbers expressing quantities of ingredients, reaction conditions, and so forth used in the specification and claims are to be understood as being modified in all instances by the term “about”. Accordingly, unless indicated to the contrary, the numerical parameters set forth in this specification and attached claims are approximations that can vary depending upon the desired properties sought to be obtained by the presently disclosed subject matter.

As used herein, the term “about,” when referring to a value or to an amount of a composition, mass, weight, temperature, time, volume, concentration, percentage, etc., is meant to encompass variations of in some embodiments+20%, in some embodiments ±10%, in some embodiments ±5%, in some embodiments ±1%, in some embodiments ±0.5%, and in some embodiments+0.1% from the specified amount, as such variations are appropriate to perform the disclosed methods or employ the disclosed compositions.

As used herein, ranges can be expressed as from “about” one particular value, and/or to “about” another particular value. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the term “and/or” when used in the context of a listing of entities, refers to the entities being present singly or in combination. Thus, for example, the phrase “A, B, C, and/or D” includes A, B, C, and D individually, but also includes any and all combinations and subcombinations of A, B, C and D.

### REFERENCES

[1] Lostetter, A. B., et al. “Polymer thick film (PTF) and flex technologies for low cost power electronics packaging.” IWIpp 2000. International Workshop on Integrated Power Packaging (Cat. No. 00EX426). IEEE, 2000.
[2] Yan, Yu, et al. “Packaging A Top-cooled 650 V/150 A GaN Power Modules with Insulated Thermal Pads and Gate-Drive Circuit.” 2021 IEEE Applied Power Electronics Conference and Exposition (APEC). IEEE, 2021.
[3] Wang, Kangping, et al. “A multiloop method for minimization of parasitic inductance in GaN-based high-frequency DC-DC converter.” IEEE Transactions on Power Electronics 32.6 (2016): 4728-4740.
[4] Jørgensen, Asger Bjørn, et al. “A fast-switching integrated full-bridge power module based on GaN eHEMT devices.” IEEE Transactions on Power Electronics 34.3 (2018): 2494-2504.
[5] Klein, Kirill, et al. “Study on packaging and driver integration with GaN switches for fast switching.” CIPS 2016; 9th International Conference on Integrated Power Electronics Systems. VDE, 2016.
[6] T. Stockmeier, P. Beckedahl, C. Göbl and T. Malzer, “SKIN: Double side sintering technology for new packages,” 2011 IEEE 23rd International Symposium on Power Semiconductor Devices and ICs, San Diego, CA, USA, 2011, pp. 324-327, doi: 10.1109/ISPSD.2011.5890856.
[7] F. Yang et al., “A Novel Packaging Method Using Flexible Printed Circuit Board for High-Frequency SiC Power Module,” 2018 1st Workshop on Wide Bandgap Power Devices and Applications in Asia (WiPDA Asia), Xi′ an, China, 2018, pp. 48-53, doi: 10.1109/WiPDAAsia.2018.8734651.
[8] https://www.rohm.com/electronics-basics/gan/gan-hemt

It will be understood that various details of the presently disclosed subject matter can be changed without departing from the scope of the presently disclosed subject matter. Furthermore, the foregoing description is for the purpose of illustration only, and not for the purpose of limitation.

What is claimed is:

1. A power electronics module comprising:
a rigid printed circuit board (PCB);
a semiconductor die; and
a flexible connection coupling the rigid PCB to the semiconductor die, wherein the flexible connection remains flexible at cryogenic temperatures.

2. A power electronics module comprising:
a rigid printed circuit board (PCB) having a slot cut-out;
a semiconductor die within the slot cut-out of the rigid PCB, wherein a top surface of the semiconductor die is lower than a top surface of the rigid PCB; and
at least one flexible PCB coupled to the semiconductor die and the rigid PCB, wherein the flexible PCB rises from the semiconductor die to a point higher than the top surface of the rigid PCB.

3. The power electronics module of claim 2, wherein the semiconductor die and the rigid PCB are mounted on a direct bonded copper (DBC) structure.

4. The power electronics module of claim 3, wherein the rigid PCB is bonded to the DBC structure using an insulation coating.

5. The power electronics module of claim 3, wherein the semiconductor die is soldered to the DBC structure, and wherein the flexible PCB is soldered to one or more first die pads on the semiconductor die and one or more connection points on the rigid PCB.

6. The power electronics module of claim 2, comprising an encapsulation material encasing the semiconductor die.

7. The power electronics module of claim 2, wherein the flexible PCB comprises two copper layers configured for power and signal connection to the semiconductor die or wherein power and signal connection is paralleled in a same layer.

8. The power electronics module of claim 7, wherein the flexible PCB comprises a flexible core layer between the two copper layers or wherein the flexible PCB comprises multiple copper layers with a flexible inner layer.

9. The power electronics module of claim 7, wherein a ratio between a thickness of the flexible core and a thickness of the copper layers is about 1:3.

10. The power electronics module of claim 2, wherein the flexible PCB comprises a bent shape that curves from the semiconductor die to the point higher than the top surface of the rigid PCB and then curves back down to the rigid PCB.

11. The power electronics module of claim 2, wherein the semiconductor die comprises a GaN high electron mobility transistor (HEMT), SiC, Si MOSFET, an IGBT, or any combination thereof, optionally wherein a surface area of the flexible PCB is less than a surface area of the rigid PCB.

12. A power electronics module comprising:
a main rigid PCB and a support rigid PCB having a cut-out and attached to the main rigid PCB on first side of the support rigid PCB;
one or more semiconductor dies sealed within the cut-out of the support rigid PCB and coupled to the main rigid PCB via one or more PCB pads per one or more semiconductor dies on a first side of the one or more semiconductor dies; and
a metal layer comprising a metal that remains soft down to cryogenic temperature, the metal layer coupled to the one or more semiconductor dies on a second side of the one or semiconductor dies opposite the first side of the one or more semiconductor dies.

13. The power electronics module of claim 12, wherein the metal layer and the support rigid PCB are disposed on a direct bonded copper (DBC) structure.

14. The power electronics module of claim 13, wherein the support rigid PCB and the metal layer are soldered to the DBC structure and a height of the support rigid PCB is slightly lower that a height of a total thickness of the metal layer and the one or more semiconductor dies.

15. The power electronics module of claim 12, wherein the metal layer comprises indium or tin.

16. The power electronics module of claim 12, comprising an encapsulation material encasing one or more semiconductor dies.

17. The power electronics module of claim 12, wherein the one or more semiconductor dies comprises two or more semiconductor dies.

18. The power electronics module of claim 12, further comprising a plate or wire attached at one end to a drain pad of the main PCB and at its opposite end between the one or more vertical semiconductor dies and the metal layer.

19. A method for manufacturing a power electronics module, the method comprising:
connecting a semiconductor die to a direct bonded copper (DBC) structure;
connecting a rigid printed circuit board (PCB) to the DBC structure; and
coupling the semiconductor die and the rigid PBC with a flexible connection, wherein the flexible connection remains flexible at cryogenic temperatures.

20. A method for manufacturing a power electronics module, the method comprising:
bonding a semiconductor die to a direct bonded copper (DBC) structure;
bonding a rigid printed circuit board (PCB) to the DBC structure so that the semiconductor die is within a slot cut-out of the rigid PCB; and
coupling at least one flexible PCB to the semiconductor die and the rigid PBC, wherein the flexible PCB rises from the semiconductor die to a point higher than the top surface of the rigid PCB.

21. A method for manufacturing a power electronics module, the method comprising:
disposing a metal layer and a support rigid PCB having a cut-out on a direct bonded copper (DBC) structure, the metal layer comprising a metal that remains soft down to cryogenic temperature;
attaching a main rigid PCB on first side of the support rigid PCB;
coupling one or more semiconductor dies to the main rigid PCB via one or more PCB pads per one or more semiconductor dies on a first side of the one or more semiconductor dies, such that the one or more semiconductor dies are sealed within the cut-out of the support rigid PCB; and
coupling the one or more semiconductor dies to the metal layer on a second side of the one or semiconductor dies opposite the first side of the one or more semiconductor dies.
